(19) United States
(12) Patent Application Publication
(10) Pub. No.: US 2012/0328798 A1
(43) Pub. Date: Dec. 27, 2012

(54) INTER-LOW-PERMITTIVITY LAYER INSULATING FILM, AND METHOD FOR FORMING INTER-LOW-PERMITTIVITY LAYER INSULATING FILM

(76) Inventors: Hideharu Shimizu, Tokyo (JP); Shuji Nagano, Moriya-shi (JP); Yoshi Ohashi, Takahagi-shi (JP); Takeshi Kada, Hiratsuka-shi (JP); Hisakatsu Sugawara, Uenohara-shi (JP)

(21) Appl. No.: 13/582,029

(22) PCT Filed: Feb. 25, 2011
(86) PCT No.: PCT/JP2011/054303

§ 371 Date: Aug. 30, 2012

(30) Foreign Application Priority Data
Mar. 1, 2010 (JP) 2010-044263

(51) Int. Cl. C09D 5/00; C23C 16/28

(52) U.S. Cl. 427/577; 106/287.14

(57) ABSTRACT

A low-permittivity interlayer insulating film of the present invention is formed by a plasma CVD method and includes at least carbon and silicon, wherein a ratio of the carbon to the silicon is 2.5 or more, and relative permittivity is 3.8 or less. Also, a film formation method of a low-permittivity interlayer insulating film of the present invention includes forming a film of an insulating film material that includes at least carbon and silicon by a plasma CVD method, wherein a hydrocarbon is not used as the insulating film material, and a ratio of the carbon to the silicon is 2.5 or more, and relative permittivity is 3.8 or less in the formed low-permittivity interlayer insulating film.

### TECHNICAL FIELD

The present invention relates to a low-permittivity interlayer insulating film and a film formation method of a low-permittivity interlayer insulating film.

Priority is claimed on Japanese Patent Application No. 2010-044263, filed Mar. 1, 2010, the content of which is incorporated herein by reference.

### BACKGROUND ART

In recent years, a wiring layer has been miniaturized with high-density integration of a semiconductor device. However, it is pointed out that a miniaturized wiring layer has the problem in which signal delay in the wiring layer is considerable and the acceleration of signal transmission rate is prevented. This signal delay is proportional to the resistance and interlayer capacity of a wiring layer. Thus, it has been expected to reduce the resistance and interlayer capacity of a wiring layer in order to realize the acceleration.

For this reason, copper has been recently used as a component of a wiring layer because copper has the smaller resistance than conventional used aluminum. In addition, an interlayer insulating film with a low relative permittivity has been used to reduce the interlayer capacity of a wiring layer.

For example, a SiO₂ film has relative-permittivity of 4.1, and a SiOF film has relative permittivity of 3.7. A SiOCH film or an organic film having a lower relative permittivity has been recently used.

However, because large amounts of holes and voids are formed in a SiOCH film or an organic film, copper of a wire is likely to be diffused in an insulating film. This diffusion of copper causes insulation breakdown and decreases reliability of a wire.

In order to prevent the diffusion of copper, it is common to form the insulating film with a diffusion barrier property which rarely has holes aid voids (hereunder, referred to as a barrier film) in the vicinity of a copper wire. It is expected that the permittivity of a barrier film is reduced without increasing holes and voids while keeping a diffusion barrier property (see Patent Literatures 1 and 2).

In the process of forming a multilayer wiring structure, insulating films such as a SiOCH film, an organic film and a barrier film are subjected to treatments such as an etching step, a washing step and a polishing step. Thus, the adhesion between insulating films and the adhesion between a metal and an insulating film are required in these treatments so as to prevent peeling. Also, it is widely known that adhesion is mainly attributed to the mechanical strength of insulating films (see Non Patent Literatures 1 and 2). Also, the mechanical strength of insulating films including adhesion is required to be high enough to prevent insulating films from damage (see Patent Literature 3). However, it is pointed out that the formation of holes and voids in an insulating film causes the problem in which the mechanical strength of an insulating film is reduced.

### CITATION LIST

### Patent Literature

### [Patent Literature 1]

Japanese Unexamined Patent Application, First Publication No. 2006-294671

### [Patent Literature 2]

Japanese Unexamined Patent Application, First Publication No. 2009-176898

### [Patent Literature 3]

International Publication, WO 2006/075578 A1

### Non Patent Literature

### [Non Parent Literature 1]

Proceedings of ADMETA2008, 2008, pp 34-35

### [Non Patent Literature 2]

Conference Proceedings AMC XXIV 2009 Materials Research Society, pp 381-386

### SUMMARY OF INVENTION

### Technical Problem

In a low-permittivity interlayer insulating film such as a SiOCH film, the reduction of relative permittivity is achieved by forming large amounts of holes and voids. However, a conventional low-permittivity interlayer insulating film has the problem of a poor barrier property for a gas and a metal due to large amounts of holes and voids. In addition, a conventional low-permittivity interlayer insulating film has the problems of small cohesive energy and poor adhesion to a film of a different composition.

A poor barrier property or poor adhesion causes insulating film destruction, electromigration and stress migration, etc, and decreases the reliability of a wire.

Against this background, it is expected that an interlayer insulating film simultaneously achieves the reduction of permittivity and the suppression of insulating film breakdown, electromigration and stress migration. However, it is difficult to simultaneously achieve these properties, and an appropriate interlayer insulating film is not actually provided.

### Solution to Problem

In order to achieve the aforementioned objects, the first embodiment of the present invention is a low-permittivity interlayer insulating film which is formed by a plasma CVD method and includes at least carbon and silicon, wherein a ratio of the carbon to the silicon is 2.5 or more, and relative permittivity is 3.8 or less.

In the present invention, the ratio of the carbon to the silicon is preferably 3.0 or more.

In the present invention, the relative dielectric constant is preferably 3.5 or less.

In the present invention, it is preferable to prevent diffusion of at least one substance selected from the group consisting of a metal, moisture and oxygen.

The low-permittivity interlayer insulating film of the present invention is preferably made of silicon, carbon and hydrogen.

The second embodiment of the present invention is a film formation method of a low-permittivity interlayer insulating film, including forming a film of an insulating film material that includes at least carbon and silicon by a plasma CVD method, wherein a hydrocarbon is not used as the insulating film material, and a ratio of the carbon to the silicon is 2.5 or more, and relative permittivity is 3.8 or less in the formed low-permittivity interlayer insulating film.

In the present invention, isobutyl trimethyl silane, diisobutyl dimethylsilane or 5-silaspiro[4,4]nonane is preferably used as the insulating film material.

### Advantageous Effects of Invention

According to a low-permittivity interlayer insulating film of the present invention, if is possible to simultaneously achieve the reduction of permittivity and the improvement of a barrier property and adhesion. Also, it is possible to increase the reliability while suppressing insulating film destruction, electromigration and stress migration.

### BRIEF DESCRIPTION OF DRAWINGS

FIG. 1 is a schematic diagram representing an example of the film formation device used in the embodiment of the present invention.

FIG. 2 is the graph representing the relationship of relative permittivity, a barrier property and the ratio of carbon to silicon (C/Si ratio).

### DESCRIPTION OF EMBODIMENTS

Hereinafter, an embodiment of a low-permittivity interlayer insulating film of the present invention is described in details.

The low-permittivity interlayer insulating film of the present embodiment is formed by a plasma CVD method for the purpose of preventing the diffusion of at least one substance of a metal, moisture and oxygen during the formation of a multilayer wiring structure, etc. For example, the low-permittivity interlayer insulating film is used as a copper diffusion-barrier film when copper is used in a wiring layer.

The low-permittivity interlayer insulating film contains at least carbon and silicon, and examples thereof in eludes a SiCH film, a SiOCH film and a SiCN film.

In the low-permittivity interlayer insulating film, the ratio of carbon to silicon (elemental ratio) is 2.5 or more, and preferably 3.0 or more. The upper limit of the ratio of carbon to silicon is preferably 4.5, and more preferably 4.0.

Also, the low-permittivity interlayer insulating film is preferably made of silicon, carbon, oxygen, nitrogen and hydrogen, and more preferably made of silicon, carbon and hydrogen.

In the low-permittivity interlayer insulating film, the relative permittivity is 3.8 or less, and preferably 3.5 or less. The lower limit of the relative permittivity is preferably 2.5, and more preferably 3.0.

Next, the film formation method of the low-permittivity interlayer insulating film of the present embodiment is described.

In the film formation method of the present embodiment, a film is formed using an insulating film material by a plasma CVD method. There is no limitation of an insulating film material as long as the low-permittivity interlayer insulating film is formed in which the ratio of carbon to silicon is 2.5 or more and the relative permittivity is 3.8 or less. Usable examples thereof are as follows.

1-1-divinyl-1-silacyclopentane, 1-1-diallyl-1-silacyclopentane, 1-1-diethynyl-1-silacyclobutane, 1-1-divinyl-1-silacyclobutane, 1-1-di-1-propynyl-1-silacyclobutane, 1-1-di-2-propynyl-1-silacyclobutane, 1-1-dipropenyl-1-silacyclobutane, 1-1-diallyl-1-silacyclobutane, 1-1-dipropyl-1-silacyclobutane, 1-1-diisopropyl-1-silacyclobutane, 1-1-di-1-butynyl-1-silacyclobutane, 1-1-di-2-butynyl-1-silacyclobutane, 1-1-di-3-butynyl-1-silacyclobutane, 1-1-di-1-butynyl-1-silacyclobutane, 1-1-di-2-butenyl-1-silacyclobutane, 1-1-di-3-butenyl-1-silacyclobutane, 1-1-dicyclobutyl-1-silacyclobutane, 1-1-dibutyl-1-silacyclobutane, 1-1-di-s-butyl-1-silacyclobutane, 1-1-di-t-butyl-1-silacyclobutane, 1-1-di-1-pentynyl-1-silacyclobutane, 1-1-di-2-pentynyl-1-silacyclobutane, 1-1-di-3-pentynyl-1-silacyclobutane, 1-1-di-1-pentenyl-1-silacyclobutane, 1-1-di-2-pentynyl-1-silacyclobutane, 1-1-di-3-pentenyl-1-silacyclobutane, 1-1-di-4-pentenyl-1-silacyclobutane, 1-1-dicyclopentyl-1-silacyclobutane, 1-1-dipentyl-1-silacyclobutane, 1-1-di-t-pentyl 1-silacyclobutane, 1-1-diethynyl-1-silacyclopentane, 1-1-divinyl-1-silacyclopentane, 1-1-di-1-propynyl-1-silacyclopentane, 1-1-di-2-propynyl-1-silacyclopentane, 1-1-dipropenyl-1-silacyclopentane, 1-1-diallyl-1-silacyclopentane, 1-1-dipropyl-1-silacyclopentane, 1-1-diisopropyl-1-silacyclopentane, 1-1-di-1-butynyl-1-silacyclopentane, 1-1-di-2-butynyl-1-silacyclopentane, 1-1-the-3-butynyl-1-silacyclopentane, 1-1-di-1-butenyl-1-silacyclopentane, 1-1-di-2-butenyl-1-silacyclopentane, 1-1-di-3-butenyl-1-silacyclopentane, 1-1-dicyclobutyl-1-silacyclopentane, 1-1-dibutyl-1-silacyclopentane, 1-1-di-s-butyl-1-silacyclopentane, 1-1-di-t-butyl-1-silacyclopentane, 1-1 di-1-pentynyl-1-silacyclopentane, 1-1-di-2-pentynyl-1-silacyclopentane, 1-1-di-3-pentynyl-1-silacyclopentane, 1-1-di-1-pentenyl-1-silacyclopentane, 1-1-di-2-pentenyl-1-silacyclopentane, 1-1-di-3-pentenyl-1-silacyclopentane, 1-1-di-4-pentenyl-1-silacyclopentane, 1-1-dicyclopentyl-1-silacyclopentane, 1-1-dipentyl-1-silacyclopentane, 1-1-di-t-pentyl-1-silacyclopentane, 1-1-diethynyl-1-silacyclohexane, 1-1-divinyl-1-silacyclohexane, 1-1-di-1-propynyl-1-silacyclohexane, 1-1-di-2-propynyl-1-silacyclohexane, 1-1-dipropenyl-1-silacyclohexane, 1-1-diallyl-1-silacyclohexane, 1-1-dipropyl-1-silacyclohexane, 1-1-diisopropyl-1-silacyclohexane, 1-1-di-1-butynyl-1-silacyclohexane, 1-1-di-2-butynyl-1-silacyclohexane, 1-1-di-3-butynyl-1-silacyclohexane, 1-1-di-1-butenyl-1-silacyclohexane, 1-1-di-2-butenyl-1-silacyclohexane, 1-1-di-3-butenyl-1-silacyclohexane, 1-1-dicyclobutyl-1-silacyclohexane, 1-1-dibutyl-1-silacyclohexane, 1-1-di-s-butyl-1-silacyclohexane, 1-1-di-t-butyl-1-silacyclohexane, 1-1-di-1-pentynyl-1-silacyclohexane, 1-1-di-2-pentynyl-1-silacyclohexane, 1-1-di-3-pentynyl-1-silacyclohexane, 1-1-di-1-pentenyl-1-silacyclohexane, 1-1-di-2-pentenyl-1-silacyclohexane, 1-1-di-3-pentenyl-1-silacyclohexane, 1-1-di-4-pentenyl-1-silacyclohexane, 1-1-dicyclopentyl-1-silacyclohexane, 1-1-dipentyl-1-silacyclohexane, 1-1-di-t-pentyl-1-silacyclohexane, 1-1-diethynyl-1-silacycloheptane, 1-1-divinyl-1-silacycloheptane, 1-1-di-1-propynyl-1-silacycloheptane, 1-1-di-2-propynyl-1-silacycloheptane, 1-1-dipropenyl-1-silacycloheptane, 1-1-diallyl-1-silacycloheptane, 1-1-dipropyl-1-silacycloheptane, 1-1-diisopropyl-1-silacycloheptane, 1-1-di-1-butynyl-1-silacycloheptane, 1-1-di-2-butynyl-1-silacycloheptane, 1-1-di-3-butynyl-1-silacycloheptane, 1-1-di-1-butenyl-1-silacycloheptane, 1-1-di-2-butenyl-1-silacycloheptane, 1-1-di-3-butenyl-1-silacycloheptane; 1-1-dicyclobutyl-1-silacycloheptane, 1-1-dibutyl-1-silacycloheptane, 1-1-di-s-butyl-1-silacycloheptane, 1-1-di-t-butyl-1-silacycloheptane, 1-1-di-1-pentynyl-1-silacycloheptane, 1-1-di-2-pentynyl-1-silacycloheptane, 1-1-di-3-pentynyl-1-silacycloheptane, 1-1-di-1-pentenyl-silacycloheptane, 1-1-di-2-pentenyl-1-silacycloheptane, 1-1-di-3-pentyl-1-silacycloheptane, 1-1-di-4-pentenyl-1-silacycloheptane, 1-1-dicyclopentyl-1-silacycloheptane, 1-1-dipentyl-1-silacycloheptane, 1-1-di-t-pentyl-1-silacycloheptane, isobutyl trimethyl silane, diisobutyl dimethyl silane, triisobutyl methyl silane, triisobutylsilane, 5-silaspiro[4,4]nonane, 5-silaspiro[4,3]octane, and 6-silaspiro[5,4]decane.

Among the aforementioned, insulating film materials, isobutyl trimethyl silane, diisobutyl dimethyl silane or 5-silaspiro[4,4]nonane is particularly preferably used.

Also, it is preferable not to use a hydrocarbon as an insulating film material.

The aforementioned insulating film material may be used in one kind or in combination with two kinds or more. When the insulating film material is used in combination with two kinds or more, the mixing ratio is not particularly limited. Any mixing ratio can be selected as long as the low-permittivity interlayer insulating film is formed in which the ratio of carbon to silicon is 2.5 or more and the relative permittivity is 3.8 or less.

Meanwhile, the elemental ratio of the low-permittivity interlayer insulating film can be controlled by using the insulating film material with a specific elemental ratio. In addition, the relative permittivity of the low-permittivity interlayer insulating film is the physical property value depending on the elemental ratio and void ratio thereof. In general, with the increase in the void ratio, the relative permittivity of the low-permittivity interlayer insulating film decreases, and the barrier property and adhesion thereof is deteriorated. In the low-permittivity interlayer insulating film of the present invention, the void ratio is preferably 0.17 or less, more preferably 0.16 or less, and most preferably 0.15 or less. There is no need to set the lower limitation of the void ratio because the void ratio is ideally zero in terms of the improvement of the barrier property and adhesion.

A carrier gas can be added to the aforementioned insulating film material during the film formation.

In this case, the gas, which is introduced into the chamber of the film formation device and used for the film formation, may be the gas made of the insulating film material or the mixed gas of this gas and a carrier gas. However, it is desirable not to use carrier gas in order to improve the diffusion-preventing property for a metal, moisture or oxygen.

Examples of a carrier gas include oxygen-free gases such as nitrogen, hydrogen and inert gases such as helium, argon, krypton and xenon, but a carrier gas is not limited to these. A carrier gas can be used in one kind or in combination with two kinds or more. There is no particular limitation to the mixing ratio of the mixed gas of carrier gases and the insulating film material.

When, the insulating film material and the carrier gas are in a gaseous state at ordinary temperature, these can be directly used. When the insulating film material and the carrier gas are in a liquid state at ordinary temperature, these are used after being subjected to gasification by a vaporizer, heating or bubbling using an inert gas such as helium.

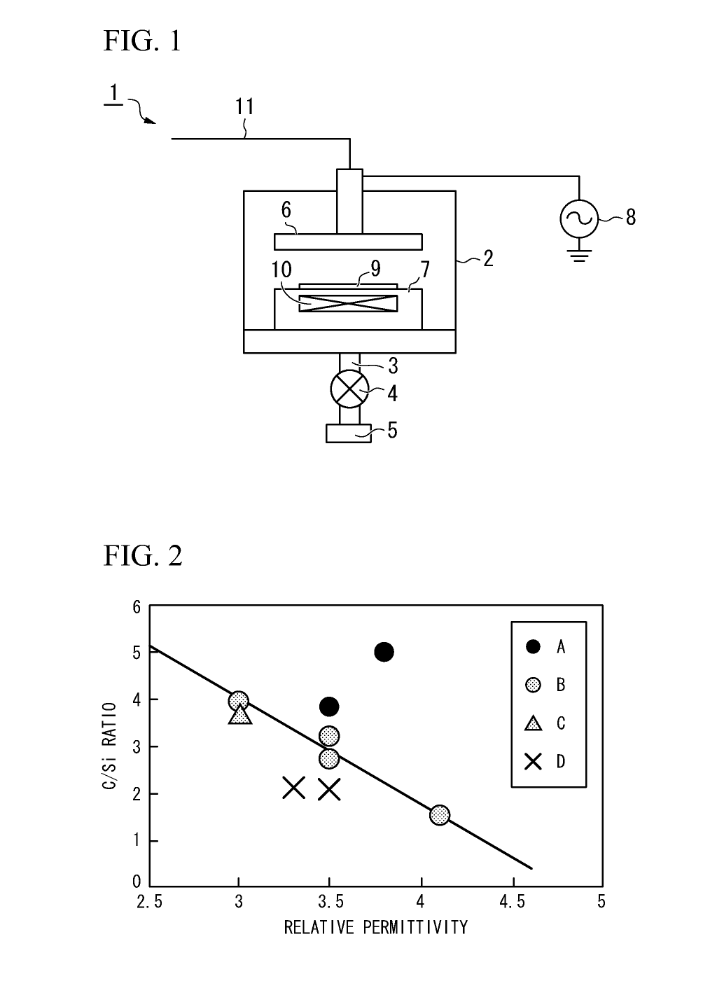

A widely known film formation device can be used to carry out a plasma CVD method. For example, the parallel plate type film formation device 1 illustrated in FIG. 1 can be used for the film formation.

The plasma him formation device 1 illustrated in FIG. 1 is equipped with the chamber 2 with the capability of depressurizing, and the chamber 2 is connected to the exhaust pump 5 through the exhaust pipe 3 and the on-off valve 4. Also, the chamber 2 is equipped with an unillustrated pressure indicator so as to measure the pressure inside the chamber 2. In the chamber 2, the upper electrode 6 and the lower electrode 7, which are a pair of flat plates facing each other, are provided. The upper electrode 6 is connected to the high-frequency power source 8 so as to apply the high-frequency current to the upper electrode 6.

Five lower electrode 7 has the function of a board which mounts the substrate 9 thereon, and the heater 10 is incorporated inside the lower electrode 7 so as to heat the substrate.

Also, the upper electrode 6 is connected to the gas supply pipe 11. This gas supply pipe 11 is connected to an unillustrated film formation gas supply source. The film formation gas is supplied from the film formation gas supply source, and is flowed off toward the lower electrode 7 while being diffused through the holes formed in the upper electrode 6.

Also, the film formation gas supply source is equipped with the vaporizer to evaporate the insulating film material, the flow regulating valve to regulate the flow rate, and the supply unit to supply the carrier gas. These gases are flowed through the gas supply pipe 11, and are flowed off into the chamber 2 through the upper electrode 6.

The substrate 9 is mounted on the lower electrode 7 in the chamber 2 of the plasma film formation device, and the film formation gas is introduced from the film formation gas supply source into the chamber 2. The high-frequency current is applied from the high-frequency power source 8 to the upper electrode 6 so as to generate plasma in the chamber 2. In this manner, the insulating film is formed on the substrate 9 by the gas-phase chemical reaction of the film formation gas.

The substrate 9 is mainly comprised of silicon water, and this silicon water may include another insulating film, a conductive film or a wiring structure, etc which were previously formed thereon.

In addition to the parallel plate type, examples of the usable plasma CVD method include ICP plasma, ECR plasma, magnetron plasma, high-frequency plasma, microwave plasma, capacitively-coupled plasma and inductively-coupled plasma. It is also possible to use two-frequency excitation plasma generated by further applying high-frequency to the lower electrode of the parallel plate type device.

The respective film formation conditions for the plasma film formation device are preferably within the following ranges, but the film formation conditions are not limited to these ranges because the appropriate conditions varies according to the kind of insulating film material to be used.

Flow rate of insulating film material: 20 to 100 cc/minute (the total flow rate in the case of two kinds or more)

Flow rate of carrier gas: 0 to 50 cc/minute

Pressure: 1 to 1330 Pa

RF power: 50 to 500 W, preferably 50 to 250 W

Substrate temperature: 400° C. less

Reaction time: 1 to 1,800 seconds

Film thickness: 100 to 200 nm

In the film formation method of the low-permittivity interlayer insulating film of the present embodiment, the ratio of carbon to silicon is 2.5 or more, and the relative permittivity is 3.8 or less. For this reasons, it is possible to improve a barrier property and adhesion. Specifically, in contest to a conventional low-permittivity interlayer insulating film in which large amounts of holes and voids are generated, holes and voids are not generated in the low-permittivity interlayer insulating him of the present embodiment, and a large amount of hydrocarbon is included in the film instead, which results in the improvement of the barrier property and adhesion. As a result, it is possible to suppress insulating film destruction, electromigration and stress migration and to increase the reliability.

In addition, in the film formation method of the low-permittivity interlayer insulating film of the present embodiment, a hydrocarbon is not used as the insulating film material. Thus, all the carbon, which is mixed in the formed low-permittivity interlayer insulating film, is originated from the insulating film material containing silicon. For this reason, carbon is uniformly mixed in the formed low-permittivity interlayer insulating film, which results in the more improvement of the barrier property and adhesion. In addition, no use of a hydrocarbon provides the merit of the simplification of the optimization of the film formation conditions for each device and the merit of no requirement of the detector for handling volatile hydrocarbon.

### EXAMPLES

Hereinafter, the present invention is described with reference to Examples and Comparative Examples. The present invention is not limited to following Examples.

In following all Examples and Comparative Examples, the SiCH films were formed as the low-permittivity interlayer insulating film by using the plasma CVD method. The evaluation method of the diffusion barrier property, which is the characteristic feature of the SiCH film, was carried out by comparing it with the SiCN film with the relative permittivity of 4.8 which has been used as the conventional barrier film. The diffusion barrier property was evaluated as follows: A for the excellent case, B for the equivalent case, C for the slightly poor case, and D for the case of no barrier property. Specifically, the copper electrode was formed, and the current-voltage characteristic was measured. Then, the voltages for the breakdown/were compared to thereby evaluate the barrier property. The adhesion was evaluated by the tape test in which one hundred pieces of the grating with one millimeter square were made, and the degree of the adhesion was evaluated by the number of the unpeeled cell.

The measurement of the ratio of carbon to silicon (C/Si ratio) was carried out by the X-ray photoelectron spectroscopy (XPS).

The measurement of the relative permittivity was carried out by the capacity-voltage measurement using the mercury probe.

The void ratio was calculated by the density measurement and the film composition.

The low-permittivity interlayer insulating film is not limited to a SiCH film.

### Example 1

In Example 1, isobutyl trimethyl silane (iBTMS) was used as the insulating film material and the SiCH film was formed under the conditions of the flow rate of 20 sccm, the pressure of 3 Torr and hie plasma power of 550 W. Then, the SiCH with the relative permittivity of 3.5 was obtained. Table 1 shows the results including the ratio of carbon to silicon (C/Si ratio), the void ratio, the barrier property and the cohesion.

These results revealed that in the low-permittivity interlayer insulating film of Example 1, the C/Si ratio was large, and dins, the void ratio was small. In addition, it was revealed that the barrier properly was equivalent to conventional one.

### Example 2

In Example 2, diisobutyl dimethyl silane (DiBDMS) was used as the insulating film material, and the SiCH film was formed under the conditions of the flow rate of 20 sccm, the pressure of 3 Torr and the plasma power of 650 W. Then, the SiCH with the relative permittivity of 3.5 was obtained. Table 1 shows the results including the ratio of carbon to silicon (C/Si ratio), the void ratio, the barrier property and the cohesion.

These results revealed that in the low-permittivity interlayer insulating film of Example 2, the C/Si ratio was large, and thus, the void ratio was small. In addition, it was revealed that the barrier property was equivalent to conventional one and that the adhesion was superior to conventional one.

### Example 3

In Example 3, diisobutyl dimethyl silane (DiBDMS) was used as the insulating film material, and the SiCH film was formed under the conditions of the flow rate of 20 sccm, the pressure of 3 Torr and the plasma power of 450 W. Then, the SiCH with the relative permittivity of 3.0 was obtained. Table 1 shows the results including the ratio of carbon to silicon (C/Si ratio), the void ratio, the barrier property and the cohesion.

These results revealed that in the low-permittivity interlayer insulating film of Example 3, the C/Si ratio was large, and thus, the void ratio was small. In addition, it was revealed that the barrier property was slightly inferior to conventional one and that the adhesion was superior to conventional one.

### Example 4

In Example 4, diisobutyl dimethyl silane (DiBDMS) was used as the insulating film material, and the SiCH film was formed under the conditions of the flow rate of 20 sccm, the pressure of 3 Torr and the plasma power of 850 W. Then, the SiCH with the relative permittivity of 3.8 was obtained. Table 1 shows the results including the ratio of carbon to silicon (C/Si ratio), the void ratio, the barrier property and the cohesion.

These results revealed that in the low-permittivity interlayer insulating film of Example 4, the C/Si ratio was large, and thus, the void ratio was small. In addition, it was revealed that both of the barrier property and the adhesion were superior to conventional ones.

### Example 5

In Example 5, 5-silaspiro[4,4]nonane (SSN) was used as the insulating film material, and the SiCH film was formed under the conditions of the how rate of 20 sccm, the pressure of 1 Torr and the plasma power of 100 W. Then, the SiCH with the relative permittivity of 3.0 was obtained. Table 1 shows the results including the ratio of carbon to silicon (C/Si ratio), the void ratio, the barrier property and the cohesion.

These results revealed that in the low-permittivity interlayer insulating film of Example 5, the C/Si ratio was large, and thus, the void ratio was small. In addition, it was revealed that the barrier property was equivalent to conventional one and that the adhesion was superior to conventional one.

### Example 6

In Example 6, 5-silaspiro[4,4]nonane (SSN) was used as the insulating film material, and the SiCH film was formed under the conditions of the flow rate of 20 sccm, the pressure of 1 Torr and the plasma power of 250 W. Then, the SiCH with the relative permittivity of 3.5 was obtained. Table 1 shows the results including the ratio of carbon to silicon (C/Si ratio), the void ratio, the barrier property and the cohesion.

These results revealed that in the low-permittivity interlayer insulating film of Example 6, the C/Si ratio was large, and thus, the void ratio was small. In addition, it was revealed that both of the barrier property and the adhesion were superior to conventional ones.

### Comparative Example 1

In Comparative Example 1, tetramethylsilane (4MS) was used as the insulating film material and the SiCH film was formed under the conditions of the flow rate of 20 sccm, the pressure of 3 Torr and the plasma power of 650 W. Then, the SiCH with the relative permittivity of 3.5 was obtained. Table 2 shows the results including the ratio of carbon to silicon (C/SI ratio), the void ratio, the barrier property and the cohesion.

These results revealed that in the low-permittivity interlayer insulating film of Comparative Example 1, the C/Si ratio was small, and the void ratio was large. In addition, it was revealed that both of the barrier property and the adhesion were inferior to conventional ones.

### Comparative Example 2

in Comparative Example 2, tetramethylsilane (4MS) was used as the insulating film material, and the SiCH film was formed under the conditions of the flow rate of 20 sccm, the pressure of 5 Torr and the plasma power of 650 W. Then, the SiCH with the relative permittivity of 3.3 was obtained. Table 2 shows the results including the ratio of carbon to silicon (C/Si ratio), the void ratio, the barrier property and the cohesion.

These results revealed that in the low-permittivity interlayer insulating film of Comparative Example 2, the C/Si ratio was small, and the void ratio was large. In addition, it was revealed that both of the barrier property and the adhesion were significantly interior to conventional ones.

### Comparative Example 3

In Comparative Example 3, the mixture obtained by mixing trimethylsilane (3MS) and ethylene at flow rate ratio of 1:1 was used as the insulating film material, and the SiCH film was firmed under the conditions of the flow rate of 60 sccm, the pressure of 8.4 Torr and the plasma power of 550 W. Then, the SiCH with the relative permittivity of 4.1 was obtained. Table 2 shows the results including the ratio of carbon to silicon (C/Si ratio), the void ratio, the barrier property and the cohesion.

These results revealed that in the interlayer insulating film of Comparative Example 3, both of the C/Si ratio and the void ratio were small, and thus, the relative permittivity was as large as 4.1. Also, a low-permittivity interlayer insulating film was not obtained. In addition, the barrier property was equivalent to conventional one.

FIG. 2 shows the relationship of relative permittivity, a barrier property and the ratio of carbon to silicon (C/Si ratio).

FIG. 2 revealed that the barrier property was superior to conventional one when the physical property values satisfy the inequality: (C/Si ratio)>−2.2358×(relative permittivity)+10.714.

TABLE 1

| | Exam- | Exam- | Exam- | Exam- | Exam- | Exam- |
|---|---|---|---|---|---|---|
| | ple 1 | ple 2 | ple 3 | ple 4 | ple 5 | ple 6 |
| C/Si | 2.72 | 3.16 | 3.69 | 5.01 | 3.95 | 3.85 |
| ratio | | | | | | |
| Relative | 3.5 | 3.5 | 3.0 | 3.8 | 3.0 | 3.5 |
| permit- | | | | | | |
| tivity | | | | | | |
| Raw | iBTMS | DiBDMS | DiBDMS | DiBDMS | SSN | SSN |
| material | | | | | | |
| Void | 0.15 | 0.13 | 0.15 | 0.1 | 0.15 | 0.11 |
| ratio | | | | | | |
| Barrier | B | B | C | A | B | A |
| property | | | | | | |
| Cu | 93 | 100 | 100 | 100 | 100 | 100 |
| adhe- | | | | | | |
| sion | | | | | | |
| SiO₂ | 81 | 99 | 95 | 100 | 100 | 100 |
| adhe- | | | | | | |
| sion | | | | | | |

TABLE 2

| | Comparative | Comparative | Comparative |
|---|---|---|---|
| | Example 1 | Example 2 | Example 3 |
| C/Si ratio | 2.07 | 2.12 | 1.5 |
| Relative permittivity | 3.5 | 3.3 | 4.1 |
| Raw material | 4MS | 4MS | 3MS |
| Void ratio | 0.18 | 0.22 | 0.13 |
| Barrier property | D | D | B |
| Cu adhesion | 85 | 20 | 95 |
| SiO₂ adhesion | 72 | 20 | 90 |

### REFERENCE SIGNS LIST

1 Film formation device
2 Chamber
3 Exhaust pipe
4 On-off valve
5 Exhaust pump
6 Upper electrode
7 Lower electrode
8 High-frequency power source
9 Substrate
10 Heater
11 Gas supply pipe

1. A low-permittivity interlayer insulating film which is formed by a plasma CVD method and comprises at least carbon and silicon, wherein
a ratio of the carbon to the silicon is 2.5 or more, and relative permittivity is 3.8 or less.

2. The low-permittivity interlayer insulating film according to claim 1, wherein the ratio of the carbon to the silicon is 3.0 or more.

3. The low-permittivity interlayer insulating film according to claim 1, wherein the relative permittivity is 3.5 or less.

4. The low-permittivity interlayer insulating film according to claim 1, which prevents diffusion of at least one substance selected front the group consisting of a metal, moisture and oxygen.

5. The low-permittivity interlayer insulating film according to claim 1, which is made of silicon, carbon and hydrogen.

6. A film formation method of a low-permittivity interlayer insulating film, comprising forming a film of an insulating film material that includes at least carbon and silicon, by a plasma CVD method, wherein
a hydrocarbon is not used as the insulating film material, and
a ratio of the carbon to the silicon is 2.5 or more, and relative permittivity is 3.8 or less in the formed low-permittivity interlayer insulating film.

7. The film formation method of a low-permittivity interlayer insulating film according to claim 6, wherein isobutyl trimethyl silane, diisobutyl dimethylsilane or 5-silaspiro[4,4]nonane is used as the insulating film material.
